(19) United States
(12) Patent Application Publication
(10) Pub. No.: US 2020/0126924 A1
(43) Pub. Date: Apr. 23, 2020

(54) FAN-OUT SEMICONDUCTOR PACKAGE

(71) Applicant: SAMSUNG ELECTRO-MECHANICS CO., LTD., Suwon-si (KR)

(72) Inventors: Yun Tae LEE, Suwon-si (KR); Han KIM, Suwon-si (KR); Jae Hyun LIM, Suwon-si (KR); Chul Kyu KIM, Suwon-si (KR)

(21) Appl. No.: 16/453,162

(22) Filed: Jun. 26, 2019

(30) Foreign Application Priority Data
Oct. 19, 2018 (KR) 10-2018-0125334

(51) Int. Cl. H01L 23/538; H01L 23/31; H01L 23/00

(52) U.S. Cl. CPC H01L 23/5389; H01L 23/3128; H01L 23/5383; H01L 2224/244; H01L 24/20; H01L 24/48; H01L 2224/48227; H01L 23/5386

(57) ABSTRACT

A fan-out semiconductor package includes a connection structure including one or more redistribution layers, a first semiconductor chip disposed on a first surface of the connection structure and having a first connection pad, a first encapsulant disposed on a first surface of the connection structure and covering at least a portion of the first semiconductor chip, and a second semiconductor chip disposed on a second surface of the connection structure and having a second connection pad, wherein the first connection pad is electrically connected to the one or more redistribution layers by a connection via of the connection structure, the second connection pad is electrically connected to the one or more redistribution layers by a wire, and the first and second connection pads are electrically connected to each other through the one or more redistribution layers.

### CROSS-REFERENCE TO RELATED APPLICATION(S)

This application claims the benefit of priority to Korean Patent Application No. 10-2018-0125334 filed on Oct. 19, 2018 in the Korean Intellectual Property Office, the disclosure of which is incorporated herein by reference.

### TECHNICAL FIELD

The present disclosure relates to a semiconductor package, for example, a fan-out semiconductor package in which an electrical connection metal may extend to a region except a region in which a semiconductor chip is disposed.

### BACKGROUND

In a semiconductor market, a continuously demanded trend is for the lightening, thinning, shortening, and miniaturizing of semiconductors. Since consumers want smaller-sized products with low battery consumption to be supplied at low cost, semiconductor manufacturers are trying to reduce chip size and package size.

A size of a semiconductor chip has been continuously reduced with a requirement for application of such a small-sized product. A semiconductor packaging technology, proposed for connection of an electrical signal when a semiconductor package is manufactured, is a fan-out Package. In the case of a conventional package-on-package (PoP) type packaging structure to which such a fan-out package is applied, a lower package and an upper package are individually manufactured to constitute a full package. In this case, a product may have a considerably great thickness and signal loss may occur.

### SUMMARY

According to aspects of the present disclosure, a fan-out semiconductor package can have less signal loss, while the package may be thinned, even if the fan-out semiconductor package includes a plurality of semiconductor chips.

According to aspects of the present disclosure, a first semiconductor chip may be embedded in a panel level package (PLP) in a face-up orientation, and a second semiconductor chip may be disposed on a redistribution layer (RDL) of the PLP and electrically connected to the RDL through a wire. As a result, the first and second semiconductor chips can be electrically connected to each other through the RDL.

According to an aspect of the present disclosure, a fan-out semiconductor package includes a connection structure including one or more redistribution layers, a first semiconductor chip, disposed on a first surface of the connection structure, having a first active surface, on which a first connection pad is disposed, and a first inactive surface opposing the first active surface, the first active surface facing the first surface of the connection structure, a first encapsulant, disposed on the first surface of the connection structure, covering at least a portion of the first semiconductor chip, and a second semiconductor chip, disposed on a second surface of the connection structure opposing the first surface, having a second active surface, on which a second connection pad is disposed, and a second inactive surface opposing the second active surface, the second inactive surface facing the second surface of the connection structure. The first connection pad is electrically connected to the one or more redistribution layers by a connection via of the connection structure, the second connection pad is electrically connected to the one or more redistribution layers by a wire, and the first and second connection pads are electrically connected to each other through the one or more redistribution layers.

According to another aspect of the present disclosure, a fan-out semiconductor package includes a frame having a through-hole and including one or more wiring layers; a first semiconductor chip, disposed in the through-hole of the frame, having a first active surface, on which a first connection pad is disposed, and a first inactive surface opposing the first active surface; a first encapsulant covering at least a portion of the first semiconductor chip; and a second semiconductor chip, disposed on one surface of the first semiconductor chip, having a second active surface, on which a second connection pad is disposed, and a second inactive surface opposing the second active surface, the second inactive surface facing the first active surface of the first semiconductor chip. The first and second semiconductor chips are arranged to be dislocated with respect to a direction perpendicular to a stacking direction such that the first connection pad is exposed, the first connection pad is electrically connected to the one or more wiring layers by a first wire, the second connection pad is electrically connected to the one or more wiring layers by a second wire, and the first and second connection pads are electrically connected to each other through the one or more wiring layers.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a schematic perspective view illustrating an example of an electronic device;

FIGS. 3A and 3B are schematic cross-sectional views illustrating states of a fan-in semiconductor package before and after being packaged;

FIG. 4 is schematic cross-sectional views illustrating a packaging process of a fan-in semiconductor package;

FIG. 5 is a schematic cross-sectional view illustrating a case in which a fan-in semiconductor package is mounted on a printed circuit board and is ultimately mounted on a mainboard of an electronic device;

FIG. 6 is a schematic cross-sectional view illustrating a case in which a fan-in semiconductor package is embedded in a printed circuit board and is ultimately mounted on a mainboard of an electronic device;

FIG. 7 is a schematic cross-sectional view illustrating a fan-out semiconductor package;

FIG. 8 is a schematic cross-sectional view illustrating a case in which a fan-out semiconductor package is mounted on a mainboard of an electronic device;

FIG. 9 is a schematic cross-sectional view illustrating an example of a fan-out semiconductor package;

FIG. 10 is a cutaway plan view taken along line I-I of the fan-out semiconductor package in FIG. 9;

FIG. 11 is a schematic cross-sectional view illustrating another example of a fan-out semiconductor package;

FIG. 12 is a schematic cross-sectional view illustrating another example of a fan-out semiconductor package; and

FIG. 13 is a schematic cross-sectional view illustrating another example of a fan-out semiconductor package.

FIG. 14 is a schematic cross-sectional view illustrating another example of a fan-out semiconductor package.

### DETAILED DESCRIPTION

Hereinafter, embodiments of the present disclosure will be described as follows with reference to the attached drawings.

Electronic Device

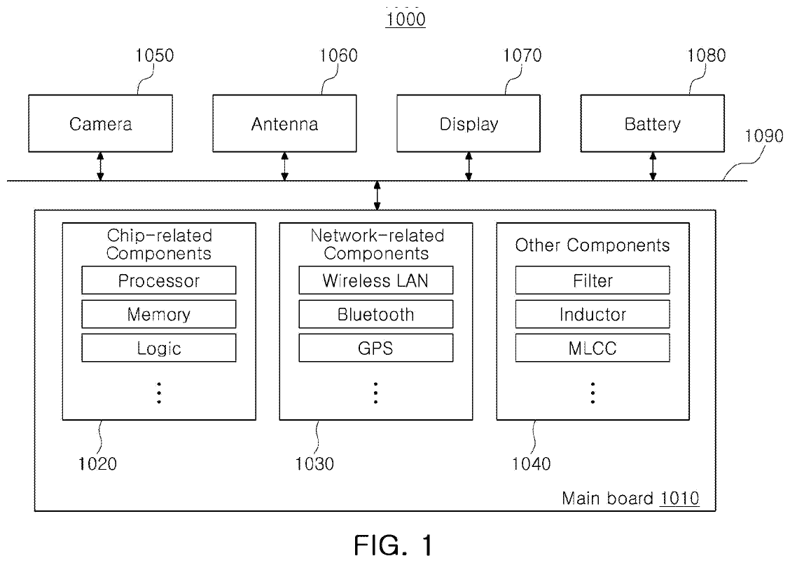

FIG. 1 is a schematic block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related components. In addition, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 or the network related components 1030 described above.

Depending on a type of the electronic device 1000, the electronic device 1000 may include other components that may or may not be physically or electrically connected to the mainboard 1010. These other components may include, for example, a camera 1050, an antenna 1060, a display 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, but may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

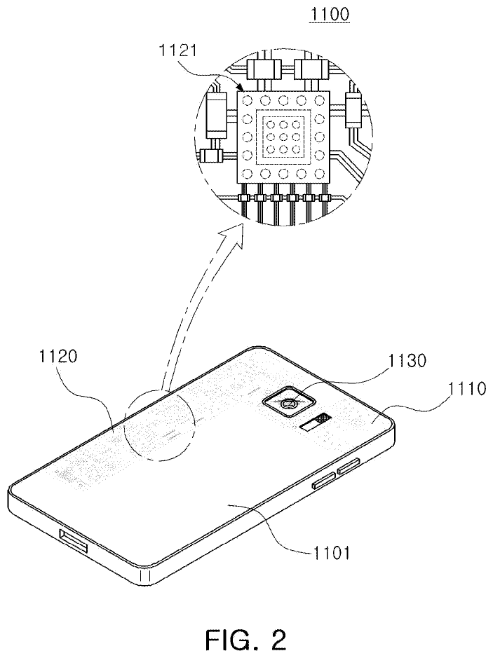

FIG. 2 is a schematic perspective view illustrating an example of an electronic device.

Referring to FIG. 2, a semiconductor package may be used for various purposes in the various electronic devices 1000 as described above. For example, a motherboard 1110 may be accommodated in a body 1101 of a smartphone 1100, and various electronic components 1120 may be physically or electrically connected to the motherboard 1110. In addition, other components that may or may not be physically or electrically connected to the motherboard 1110, such as a camera module 1130, may be accommodated in the body 1101. Some of the electronic components 1120 may be the chip related components, for example, a semiconductor package 1121, but are not limited thereto. The electronic device is not necessarily limited to the smartphone 1100, but may be other electronic devices as described above.

Semiconductor Package

Generally, numerous fine electrical circuits are integrated in a semiconductor chip. However, the semiconductor chip may not serve as a finished semiconductor product in itself, and may be damaged due to external physical or chemical impacts. Therefore, the semiconductor chip itself may not be used, but may be packaged and used in an electronic device, or the like, in a packaged state.

Here, semiconductor packaging is required due to the existence of a difference in a circuit width between the semiconductor chip and a mainboard of the electronic device in terms of electrical connections. In detail, a size of connection pads of the semiconductor chip and an interval between the connection pads of the semiconductor chip are very fine, but a size of component mounting pads of the mainboard used in the electronic device and an interval between the component mounting pads of the mainboard are significantly larger than those of the semiconductor chip. Therefore, it may be difficult to directly mount the semiconductor chip on the mainboard, and packaging technology for buffering a difference in a circuit width between the semiconductor chip and the mainboard is required.

A semiconductor package manufactured by the packaging technology may be classified as a fan-in semiconductor package or a fan-out semiconductor package depending on a structure and a purpose thereof.

The fan-in semiconductor package and the fan-out semiconductor package will hereinafter be described in more detail with reference to the drawings.

Fan-in Semiconductor Package

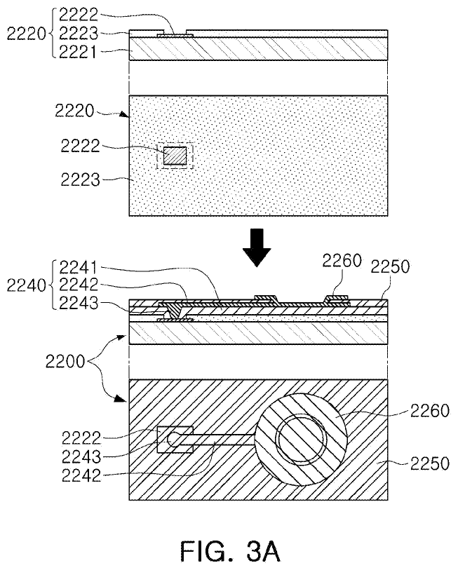

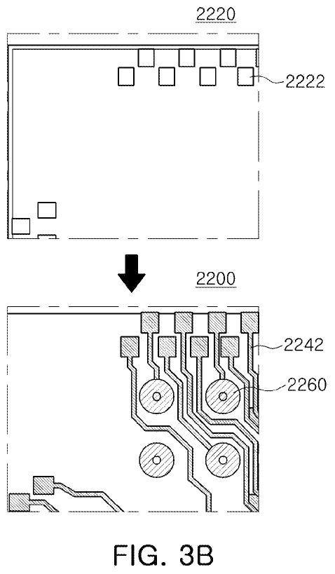

FIGS. 3A and 3B are schematic cross-sectional views illustrating states of a fan-in semiconductor package before and after being packaged.

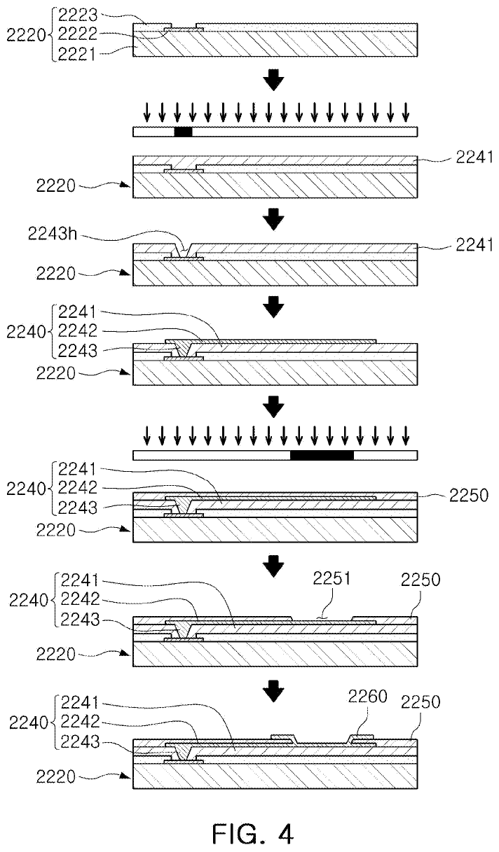

FIG. 4 is schematic cross-sectional views illustrating a packaging process of a fan-in semiconductor package.

Referring to FIGS. 3A to 4, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation layer 2223 such as an oxide layer, a nitride layer, or the like, formed on one surface of the body 2221 and covering at least portions of the connection pads 2222. In this case, since the connection pads 2222 may be significantly small, it may be difficult to mount the integrated circuit (IC) on an intermediate level printed circuit board (PCB) as well as on the mainboard of the electronic device, or the like.

Therefore, a connection member 2240 may be formed depending on a size of the semiconductor chip 2220 on the semiconductor chip 2220 in order to redistribute the connection pads 2222. The connection member 2240 may be formed by forming an insulating layer 2241 on the semiconductor chip 2220 using an insulating material such as a photoimagable dielectric (PID) resin, forming via holes 2243h opening the connection pads 2222, and then forming wiring patterns 2242 and vias 2243. Then, a passivation layer 2250 protecting the connection member 2240 may be formed, an opening 2251 may be formed, and an underbump metal layer 2260, or the like, may be formed. That is, a fan-in semiconductor package 2200 including, for example, the semiconductor chip 2220, the connection member 2240, the passivation layer 2250, and the underbump metal layer 2260 may be manufactured through a series of processes.

As described above, the fan-in semiconductor package may have a package form in which all of the connection pads, for example, input/output (I/O) terminals, of the semiconductor chip are disposed inside the semiconductor chip, and may have excellent electrical characteristics and be produced at a low cost. Therefore, many elements mounted in smartphones have been manufactured in a fan-in semiconductor package form. In detail, many elements mounted in smartphones have been developed to implement a rapid signal transfer while having a compact size.

However, since all I/O terminals need to be disposed inside the semiconductor chip in the fan-in semiconductor package, the fan-in semiconductor package has significant spatial limitations. Therefore, it is difficult to apply this structure to a semiconductor chip having a large number of I/O terminals or a semiconductor chip having a compact size. In addition, due to the disadvantage described above, the fan-in semiconductor package may not be directly mounted and used on the mainboard of the electronic device. The reason is that even though a size of the I/O terminals of the semiconductor chip and an interval between the I/O terminals of the semiconductor chip are increased by a redistribution process, the size of the I/O terminals of the semiconductor chip and the interval between the I/O terminals of the semiconductor chip are not enough to directly mount the fan-in semiconductor package on the mainboard of the electronic device.

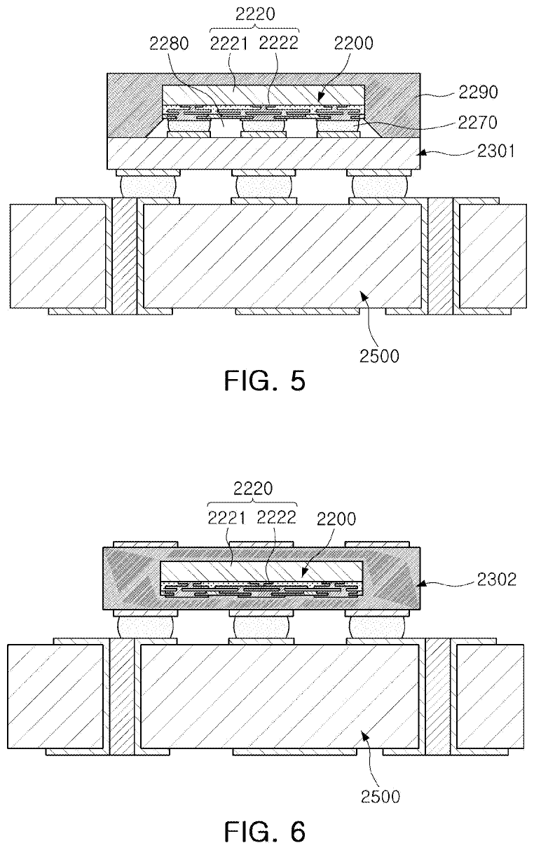

FIG. 5 is a schematic cross-sectional view illustrating a case in which a fan-in semiconductor package is mounted on a ball grid array (BGA) substrate and is ultimately mounted on a mainboard of an electronic device.

FIG. 6 is a schematic cross-sectional view illustrating a case in which a fan-in semiconductor package is embedded in a BGA substrate and is ultimately mounted on a mainboard of an electronic device.

Referring to FIGS. 5 and 6, in a fan-in semiconductor package 2200, connection pads 2222, that is, I/O terminals, of a semiconductor chip 2220 may be redistributed through a BGA substrate 2301, and the fan-in semiconductor package 2200 may be ultimately mounted on a mainboard 2500 of an electronic device in a state in which it is mounted on the BGA substrate 2301. In this case, solder balls 2270, and the like, may be fixed by an underfill resin 2280, or the like, and an outer side of the semiconductor chip 2220 may be covered with a molding material 2290, or the like. Alternatively, a fan-in semiconductor package 2200 may be embedded in a separate BGA substrate 2302, connection pads 2222, that is, I/O terminals, of the semiconductor chip 2220 may be redistributed by the BGA substrate 2302 in a state in which the fan-in semiconductor package 2200 is embedded in the BGA substrate 2302, and the fan-in semiconductor package 2200 may be ultimately mounted on a mainboard 2500 of an electronic device.

As described above, it may be difficult to directly mount and use the fan-in semiconductor package on the mainboard of the electronic device. Therefore, the fan-in semiconductor package may be mounted on the separate BGA substrate and be then mounted on the mainboard of the electronic device through a packaging process or may be mounted and used on the mainboard of the electronic device in a state in which it is embedded in the BGA substrate.

Fan-Out Semiconductor Package

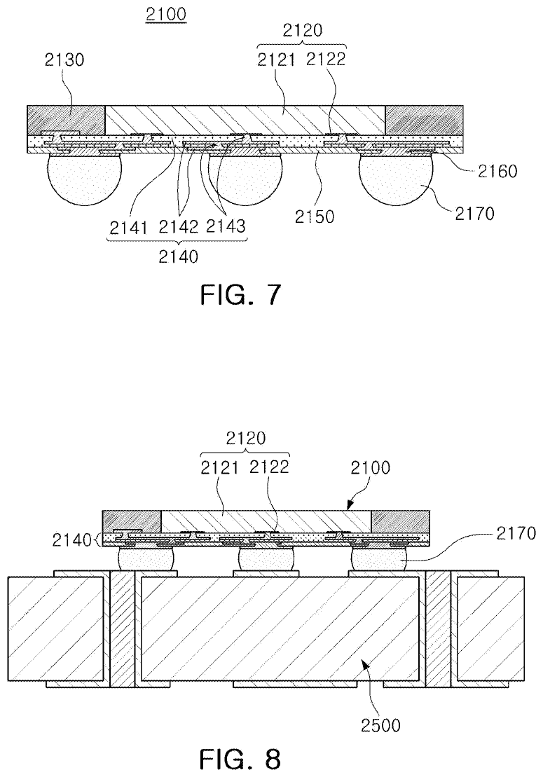

FIG. 7 is a schematic cross-sectional view illustrating a fan-out semiconductor package.

Referring to FIG. 7, in a fan-out semiconductor package 2100, for example, an outer side of a semiconductor chip 2120 may be protected by an encapsulant 2130, and connection pads 2122 of the semiconductor chip 2120 may be redistributed outwardly of the semiconductor chip 2120 by a connection member 2140. In this case, a passivation layer 2150 may further be formed on the connection member 2140, and an underbump metal layer 2160 may further be formed in openings of the passivation layer 2150. Solder balls 2170 may further be formed on the underbump metal layer 2160. The semiconductor chip 2120 may be an integrated circuit (IC) including a body 2121, the connection pads 2122, a passivation layer (not illustrated), and the like. The connection member 2140 may include an insulating layer 2141, redistribution layers 2142 formed on the insulating layer 2141, and vias 2143 electrically connecting the connection pads 2122 and the redistribution layers 2142 to each other.

As described above, the fan-out semiconductor package may have a form in which I/O terminals of the semiconductor chip are redistributed and disposed outwardly of the semiconductor chip through the connection member formed on the semiconductor chip. As described above, in the fan-in semiconductor package, all I/O terminals of the semiconductor chip need to be disposed inside the semiconductor chip. Therefore, when a size of the semiconductor chip is decreased, a size and a pitch of balls need to be decreased, such that a standardized ball layout may not be used in the fan-in semiconductor package. On the other hand, the fan-out semiconductor package has the form in which the I/O terminals of the semiconductor chip are redistributed and disposed outwardly of the semiconductor chip through the connection member formed on the semiconductor chip as described above. Therefore, even in a case in which a size of the semiconductor chip is decreased, a standardized ball layout may be used in the fan-out semiconductor package as it is, such that the fan-out semiconductor package may be mounted on the mainboard of the electronic device without using a separate BGA substrate, as described below.

FIG. 8 is a schematic cross-sectional view illustrating a case in which a fan-out semiconductor package is mounted on a mainboard of an electronic device.

Referring to FIG. 8, a fan-out semiconductor package 2100 may be mounted on a mainboard 2500 of an electronic device through solder balls 2170, or the like. That is, as described above, the fan-out semiconductor package 2100 includes the connection member 2140 formed on the semiconductor chip 2120 and capable of redistributing the connection pads 2122 to a fan-out region that is outside of a size of the semiconductor chip 2120, such that the standardized ball layout may be used in the fan-out semiconductor package 2100 as it is. As a result, the fan-out semiconductor package 2100 may be mounted on the mainboard 2500 of the electronic device without using a separate BGA substrate, or the like.

As described above, since the fan-out semiconductor package may be mounted on the mainboard of the electronic device without using the separate BGA substrate, the fan-out semiconductor package may be implemented at a thickness lower than that of the fan-in semiconductor package using the BGA substrate. Therefore, the fan-out semiconductor package may be miniaturized and thinned. In addition, the fan-out electronic component package has excellent thermal characteristics and electrical characteristics, such that it is particularly appropriate for a mobile product. Therefore, the fan-out electronic component package may be implemented in a form more compact than that of a general package-on-package (POP) type using a printed circuit board (PCB), and may solve a problem due to the occurrence of a warpage phenomenon.

Meanwhile, the fan-out semiconductor package refers to package technology for mounting the semiconductor chip on the mainboard of the electronic device, or the like, as described above, and protecting the semiconductor chip from external impacts, and is a concept different from that of a printed circuit board (PCB) such as a BGA substrate, or the like, having a scale, a purpose, and the like, different from those of the fan-out semiconductor package, and having the fan-in semiconductor package embedded therein.

Hereinafter, a fan-out semiconductor package, having less signal loss, which may be thinned, even if the fan-out semiconductor package includes a plurality of semiconductor chips, will be described with reference to accompanying drawings.

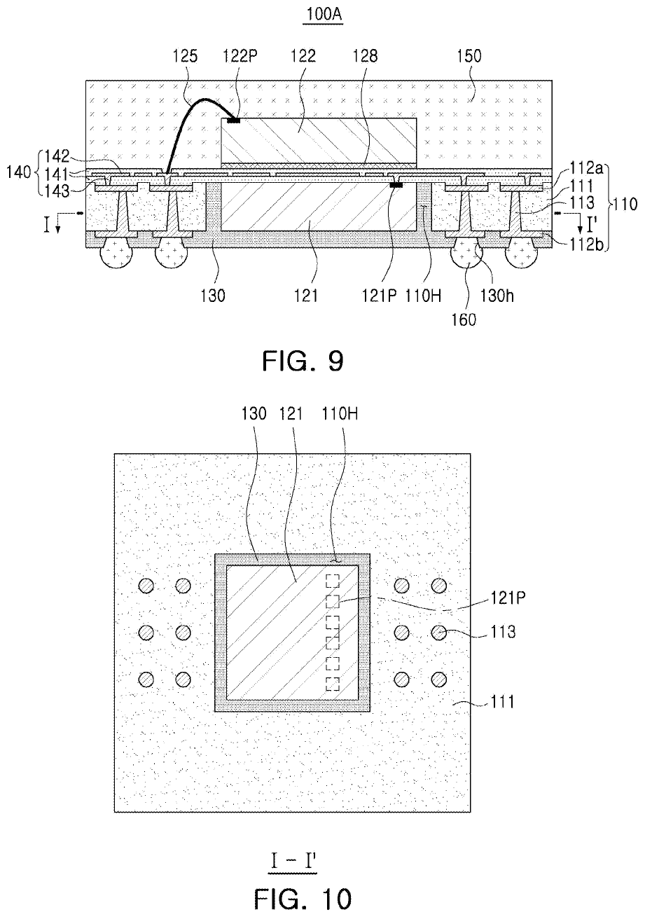

FIG. 9 is a schematic cross-sectional view illustrating an example of a fan-out semiconductor package, and FIG. 10 is a cutaway plan view taken along line I-I of the fan-out semiconductor package in FIG. 9.

Referring to FIGS. 9 and 10, a semiconductor package 100A according to an example embodiment includes a frame 110 having a through-hole 110H and including one or more wiring layers 112a and 112b, a first semiconductor chip 121, disposed in the through-hole 110H of the frame 110, having a first active surface, on which the first connection pad 121P is disposed, and a first inactive surface opposing the first active surface, a first encapsulant 130 covering the frame and a first inactive surface of the first semiconductor chip 121 and filling at least a portion of the through-hole 110H, a connection structure 140, disposed on the frame 110 and the first active surface of the first semiconductor chip 121, including one or more redistribution layers 142, a second semiconductor chip 122, disposed on the connection structure 140, having a second active surface, on which the second connection pad 122P is disposed, and a second inactive surface opposing the second active surface, a second encapsulant 150, disposed on the connection structure 140, covering at least a portion of the second semiconductor chip 122, a plurality of openings 130H, formed in a region of the first encapsulant 130 covering the frame 110 on a side opposing a side on which the connection structure 140 is disposed, each exposing at least a portion of the wiring layer 112b disposed on a side of the first encapsulant 130 opposing a side on which the first connection structure 140 is disposed, and a plurality of electrical connection metals 160, respectively disposed in the plurality of openings 130h, each being electrically connected to the exposed wiring layer 112b.

The first semiconductor chip 1221 is disposed in such a manner that the first active surface faces a bottom surface of the connection structure 140, on the basis of the drawings, the second semiconductor chip 122 is disposed in such a manner that the second inactive surface faces a top surface of the connection structure, on the basis of the drawings, the first connection pad 121P is electrically connected to the redistribution layer 142 through a connection via 143 of the connection structure 140, and the second connection pad 122P is electrically connected to the redistribution layer 142 through a wire 125. As a result, the first and second connection pads 121P and 122P are electrically connected to each other through the redistribution layer 142. The second semiconductor chip 122 may be disposed in such a manner that the second inactive surface is attached to a top surface of the connection structure 140 via an adhesive 128. The adhesive 128 may be a known die attach film (DAF).

For example, the fan-out semiconductor package 100A includes the connection structure 140, including the redistribution layer 142, disposed between the first semiconductor chip 121 and the second semiconductor chip 122. In this case, the first semiconductor chip 121 is disposed in a face-up orientation to be electrically connected to the redistribution layer 142 through the connection via 143, and the second semiconductor chip 122 is electrically connected to the redistribution layer 142 through a wire. Thus, a signal transmission path between the first and second semiconductor chips 121 and 122 may be significantly reduced. As a result, loss of signal characteristics may be significantly reduced. Since such a structure is a structure in which the first and second semiconductor chips 121 and 122 are disposed without an additional interposer, an overall thickness of the package 100A may be significantly reduced. For example, the fan-out semiconductor package 100A, having less signal loss, which may be thinned, even if the fan-out semiconductor package 100A includes a plurality of semiconductor chips, may be provided. The fan-out semiconductor package 100A may be usefully applied to a memory package or the like.

Hereinafter, each component included in the fan-out semiconductor package 100A according to an example embodiment will be described in detail.

The frame 110 includes the one or more wiring layers 112a and 112b, redistributing the first and second connection pads 121P and 122P of the first and second semiconductor chips 121 and 122, and may decrease the number of layers of the connection structure 140. In addition, rigidity of the package 100A may be maintained depending on a detail material of the insulating layer 111 of the frame 110, and the frame 110 may serve to secure thickness uniformity of the first encapsulant 130, and the like. An upper portion and a lower portion of the fan-out semiconductor package 100a may be electrically connected by the frame 110. The frame 110 may have the through-hole 110H, and the semiconductor chip 121 may be disposed in the through-hole 110H. The through-hole 110H may be formed to surround a periphery of a side surface of the first semiconductor chip 121. Instead of the frame 110, another electrical connection structure such as a metal post, capable of electrically connecting the upper and lower portions of the fan-out semiconductor package 100a, may be disposed.

As an example, the frame 110 may include an insulating layer 111 disposed in contact with the connection structure 140, a first wiring layer 112a embedded in the insulating layer 111 while being in contact with the connection structure 140, a second wiring layer 112b disposed on a side opposing a side of the insulating layer 111 on which the first wiring layer 112a is disposed, and a connection via layer 113 penetrating through the insulating layer 111 and electrically connecting the first and second wiring layers 112a and 112b. When the first wiring layer 112a is embedded in the insulating layer 111, a step, formed with respect to the insulating layer 111 due to a thickness of the first wiring layer 112a, is significantly reduced. Accordingly, since an insulation distance of the connection structure 140 has a constant value, a high-density wiring design of the connection structure 140 may be easily performed. A surface of the first wiring layer 112a, disposed in contact with the connection structure 140 of the first wiring layer 112a, may have a predetermined step with respect to a surface of the insulating layer 111 disposed in contact with the connection structure 140. With such a predetermined step structure, the insulating layer 111 may prevent the first encapsulant 130 from bleeding to the first wiring layer 112a to address a bleeding issue.

A material of the insulating layer 111 is not limited. For example, an insulating material may be used as the material of the insulating layer 111. In this case, the insulating material may be a thermosetting resin such as an epoxy resin, a thermoplastic resin such as a polyimide resin, a resin in which the thermosetting resin or the thermoplastic resin is mixed with an organic filler or is impregnated in a core material such as a glass fiber (or a glass cloth or a glass fabric) together with an inorganic filler, for example, prepreg, Ajinomoto Build up Film (ABF), FR-4, Bismaleimide Triazine (BT), or the like. In detail, prepreg or ABF may be used as the insulating material.

The first and second wiring layers 112a and 112b may serve to redistribute the first and second connection pads 121P and 122P of the first and second semiconductor chips 121 and 122, and may serve to provide a pad pattern for a connection via layer 113a for connecting an upper portion and a lower portion of the package 100A. A material of each of the first and second wiring layers 112a and 112b may be a metal material such as copper (Cu), aluminum (Al), silver (Ag), tin (Sn), gold (Au), nickel (Ni), lead (Pb), titanium (Ti), or alloys thereof. The first and second wiring layers 112a and 112b may perform various functions depending on designs of corresponding layers. For example, the first and second wiring layers 112a and 112b may include ground (GND) patterns, power (PWR) patterns, signal (S) patterns, and the like. The signal (S) patterns may include various signals, such as a data signal and the like, except the ground (GND) patterns, the power (PWR) patterns, and the like. In addition, the first and second wiring layers 112a and 112b may include a via pad, an electrical connection metal pad, and the like. At least a portion of the electrical connection metal pad may be exposed by an opening 130h formed in the first encapsulant 130. As necessary, a surface treatment layer, not illustrated, may be formed on the electrical connection metal pad. The surface treatment layer, not illustrated, may be limited as long as it is known in the art, and may be formed by, for example, electro-gold plating, immersion gold plating, organic solderability preservative (OSP) or immersion tin plating, immersion silver plating), electroless nickel and immersion gold (ENIG), direct immersion gold (DIG) plating, hot air solder leveling (HASL), or the like.

The connection via layer 113 may electrically connect the first and second wiring layers 112a and 112b, disposed on different layers to each other, to form an electrical path in the frame 110. A material of the connection via layer 113 may be a metal material. The connection via layer 113 may be a filled via completely filled with the metal material, or a conformal via in which a metal material is formed along a wall surface of a via hole. Moreover, the connection via layer 113 may have a tapered shape or the like. The connection via layer 113 may have a tapered shape. Since a portion of a pad pattern of the first wiring layer 112a may serve as a stopper when a via hole for the connection via layer 113 is formed, it is advantageous in process that the connection via layer 113 has a tapered shape in which a lower side has a width greater than a width of an upper side, on the basis of the drawings. However, in this case, the connection via layer 113 may be integrated with a portion of a pattern of the second wiring layer 112b.

Each of the first and second semiconductor chips 121 and 122 may be an integrated circuit die in which hundreds to hundreds of thousands of components are integrated in a single chip. In this case, the first and second semiconductor chips 121 and 122 may be homogeneous integrated circuit dies, for example, homogeneous memory dies. A memory die may be a volatile memory (for example, a DRAM), a nonvolatile memory (for example, a ROM), a flash memory, or the like.

Each of the first and second semiconductor chips 121 and 122 may be formed based on an active wafer. In this case, a base material of a body may be silicon (Si), germanium (Ge), gallium arsenide (GaAs), or the like. Various circuits may be formed on the body. The first and second connection pads 121P and 122P may electrically connect the first and second semiconductor chips 121 and 122 to other components. A material of each of the connection pads 121P and 122P may be a metal such as aluminum (Al), copper (Cu), or the like, but is not limited thereto. Surfaces, on which the first and second connection pads 121P and 122P are disposed, are first and second active surfaces, respectively. Surfaces, opposing the first and second active surfaces, are inactive surfaces, respectively. A passivation layer, not illustrated, may be disposed on the body 121 to expose the respective first and second connection pads 121P and 122P, and may be an oxide layer, a nitride layer, or the like. Alternatively, the passivation layer, not illustrated, may be a double layer of an oxide layer and a nitride layer. An insulating layer, not illustrated, or the like, may be further disposed in other required positions, and a redistribution layer, not illustrated, may be formed on an active surface. The first and second active surfaces refer to uppermost or lowermost surfaces while including such a passivation layer, not illustrated.

The first semiconductor chip 121 may be electrically connected to the redistribution layer 142 of the connection structure 140 through the connection via 143 of the connection structure 140, and the second semiconductor chip 122 may be electrically connected to the redistribution layer 142 of the connection structure 140 trough a wire. The wire may be a metal wire including a metal such as copper (Cu), gold (Au), or the like.

The first encapsulant 130 may protect the frame 110, the first semiconductor chip 121, and the like. An encapsulation form is not limited as long as the encapsulant 130 covers at least a portion of the first semiconductor chip 121. For example, the encapsulant 130 may cover at least a portion of the frame 110 and at least a portion of the first inactive surface of the first semiconductor chip 121, and may fill at least a portion of the through-hole 110H. A detailed material of the first encapsulant 130 is not limited. For example, an insulating material may be used as the material of the first encapsulant 130. The insulating material may be a material including an inorganic filler and an insulating resin, for example, a thermosetting resin such as an epoxy resin, a thermoplastic resin such as a polyimide resin, a resin having a reinforcing material, such as an inorganic filler impregnated in the thermosetting resin and the thermoplastic resin, such as ABF, FR-4, BT, or the like. Alternatively, an epoxy molding compound (EMC), a photoimageable dielectric (PID), or the like may be used as the insulating material. As necessary, a material, in which a thermosetting resin or a thermoplastic resin is impregnated with an inorganic filler and/or a core material such as a glass fiber (or a glass cloth or a glass fabric), for example, prepreg may also be used as the insulating material.

The first active surface of the first semiconductor chip 121 may be coplanar with a surface disposed in contact with the connection structure 140 of the first encapsulant 130. Also the first active surface of the first semiconductor chip 121 may be coplanar with a surface disposed in contact with the connection structure 140 of the frame 110, for example, a surface of the insulating layer 111 disposed in contact with the connection structure 140. In this case, the insulting layer 141 of the connection structure 140 may be formed without undulation, which may be useful in a high-density circuit design of the connection structure 140.

The connection structure 140 may redistribute the first and second connection pads 121P and 122P of the first and second semiconductor chips 121 and 122, and may electrically connect the first and second connection pads 121P and 122P to each other. Tens to millions of first and second connection pads 121P and 122P, having various functions, may be redistributed through the connection structure 140, and may be physically and/or electrically connected to an external component through the electrical connection metal 160 depending on functions thereof. The connection structure 140 includes an insulating layer 141, a redistribution layer 142 disposed on the insulating layer 141, and a connection via 143 penetrating through the insulating layer 141 and electrically connecting the redistribution layer 142 to the first wiring layer 112a and the first connection pad 121P. Unlike the drawings, not only the insulating layer 141 but also the redistribution layer 142 and the connection via 143 may also be multiple layers. In this case, at least one layer of the connection via 143 may electrically connect redistribution layers 142 of different layers to each other.

A material of the insulating layer 141 may be an insulating material. The insulating material may be a photosensitive material such as a photoimageable dielectric (PID). For example, the first insulating layer 141 may be a photosensitive layer. When the first insulating layer 141 has photosensitive properties, the insulating layer 141 may be further thinned and a fine pitch of the connection via 143 may be more easily achieved. The insulating layer 141 may be a photosensitive insulating layer including an insulating resin and an inorganic filler. When the insulating layer 141 includes multiple layers, materials of the multiple layers may be identical to each other and, as necessary, may be different from each other. When the insulating layer 141 includes multiple layers, the multiple layers may be integrated with each other so that boundaries therebetween are not readily apparent. As necessary, an underlying insulating layer 141, in which the redistribution layer 142 and the connection via 143 are formed, may include the above-mentioned PID, and an overlying insulating layer 141, covering the redistribution layer 142, may include an ABF or a known solder resist, but materials thereof are not limited thereto.

The redistribution layer 142 may substantially serve to redistribute the first and second connection pads 121P and 122P. A material of the redistribution layer 142 may be a metal material such as copper (Cu), aluminum (Al), silver (Ag), tin (Sn), gold (Au), nickel (Ni), lead (Pb), titanium (Ti), or alloys thereof. The redistribution layer 142 may perform various functions depending on a design of a corresponding layer. For example, the redistribution layer 142 may include a ground (GND) pattern, a power (PWR) pattern, a signal (S) pattern, and the like. The signal (S) pattern includes various signals, for example, a data signal, and the like, except the ground (GND) pattern, the power (PWR) pattern, and the like. The ground (GND) pattern and the power (PWR) pattern may be identical to each other. The redistribution layer 142 may include a wire pad, a via pad, an electrical connection metal pad, or the like. As necessary, a surface treatment layer, not illustrated, may be formed on a surface of a wire pad having at least a portion exposed for connection to the wire 125. The surface treatment layer, not illustrated, may be formed by, for example, electro-gold plating, immersion gold plating, organic solderability preservative (OSP) or immersion tin plating, immersion silver plating), electroless nickel and immersion gold (ENIG), direct immersion gold (DIG) plating, hot air solder leveling (HASL), or the like, but a forming method thereof is not limited thereto.

Each of the first and second wiring layers 112a and 112b of the frame 110 may have a thickness greater than a thickness of the redistribution layer 142 of the connection structure 140. The frame 110 may have a thickness greater than or equal to a thickness of the first semiconductor chip 121, such that each of the first and second wiring layers 112a and 112b may have a larger size depending on a scale thereof. Meanwhile, the redistribution layer 142 of the connection structure 140 may be formed to have a relatively smaller thickness than each of the first and second wiring layers 112a and 112b for a high-density design of the connection structure 140.

The connection via 143 may electrically connect the redistribution layer 142, the first connection pad 121P, or the like, formed on different layers, to form an electrical path in the package 100A. A material of the connection via may be a metal material such as copper (Cu), aluminum (Al), silver (Ag), tin (Sn), gold (Au), nickel (Ni), lead (Pb), titanium (Ti), or alloys thereof. The connection via 143 may be a filled via completely filled with the metal material, or a conformal via in which a metal material is formed along a wall surface of a via hole. Connection vias 143 may have tapered shapes in the same direction. In this case, a tapered direction of the connection via 143 may be opposite to a tapered direction of a connection via of the connection via layer 113.

The second encapsulant 150 may be additionally configured protect the second semiconductor chip 122. An encapsulation form of the second encapsulant 150 is not limited as long as the second encapsulant 150 covers at least a portion of the second semiconductor chip 122. For example, the second encapsulant 150 may be disposed on the connection structure 140 to cover a second inactive surface and a side surface of the second semiconductor chip 122. In addition, the second encapsulant 150 may encapsulate a wire. For example, the second encapsulant 150 may cover at least a portion of the wire. A detailed material of the first encapsulant 130 is not limited. For example, an insulating material may be used as the material of the second encapsulant 150. As described above, the insulating material may be a material including an inorganic filler and an insulating resin, for example, a thermosetting resin such as an epoxy resin, a thermoplastic resin such as a polyimide resin, a resin having a reinforcing material, such as an inorganic filler impregnated in the thermosetting resin and the thermoplastic resin, such as ABF, FR-4, BT, or the like. Alternatively, an EMC, a PID, or the like may be used as the insulating material. As necessary, a material, in which a thermosetting resin or a thermoplastic resin is impregnated with an inorganic filler and/or a core material such as a glass fiber, for example, prepreg may also be used as the insulating material.

The electrical connection metal 160 is additionally configured to physically and/or electrically connect the semiconductor package 100A to an external component. For example, the semiconductor package 100A may be mounted on a mainboard of an electronic device through the electrical connection metal 160. The electrical connection metal 160 may be formed of a low melting point metal such as tin (Sn) or a Sn-containing alloy. More specifically, the electrical connection metal 160 may be formed of a solder or the like, but is merely an example and a material thereof is not limited thereto. The electrical connection metal 160 may be a land, a ball, a pin, or the like. The electrical connection metal 160 may include multiple layers or a single layer. When the electrical connection metal 160 includes multiple layers, the electrical connection metal 160 may include a copper (Cu) pillar and a solder. When the electrical connection metal 160 includes a single layer, the electrical connection metal 160 may include a tin-silver solder or copper (Cu). However, these are also merely examples, and a structure and a material of the electrical connection metal 160 are not limited thereto.

The number, an interval, a dispositional form, and the like, of the electrical connection metal 160 are not limited, but may be sufficiently modified depending on design by those skilled in the art. For example, several tens to several tens of thousands of electrical connection metals 160 may be provided according to the number of first and second connection pads 121P and 122P, and a greater or smaller number of electrical connection metals 160 may be provided.

The electrical connection metals 160 may all be disposed in a fan-out region. The term “fan-out region” refers to a region except a region in which the first semiconductor chip 121 is disposed from a viewpoint perpendicular to a stacking direction. The fan-out package may have improved reliability as compared to a fan-in package, may allow a plurality of input/output (I/O) terminals to be implemented, and may facilitate a three-dimensional (3D) interconnection. Moreover, as compared to a ball grid array (BGA) package, a land grid array (LGA) package, or the like, the fan-out package may be manufactured to have a small thickness, and may be superior in price competitiveness.

The electrical connection metal 160 is disposed only in the fan-out region, so that there is substantially no interference with an electrical connection metal pad during a design process of redistributing the first and second connection pads 121P and 122P of the first and second semiconductor chips 121 and 122 of the redistribution layer 142. Therefore, the number of layers of the redistribution layer 142 may be more usefully decreased. For example, designing an additional redistribution layer on a side opposing a side of the first encapsulant 130, on which the connection structure 140 is disposed, may be omitted.

Although not illustrate in the drawings, an additional passive component may be disposed in the through-hole 110H in parallel to the first semiconductor chip 121. A metal layer may be disposed on a wall surface of the through-hole 110H to shield electromagnetic interference and to obtain a heat dissipation effect. As necessary, an underbump metal may be disposed in the opening 130h of the first encapsulant 130 to improve reliability of connection to the electrical connection metal 160.

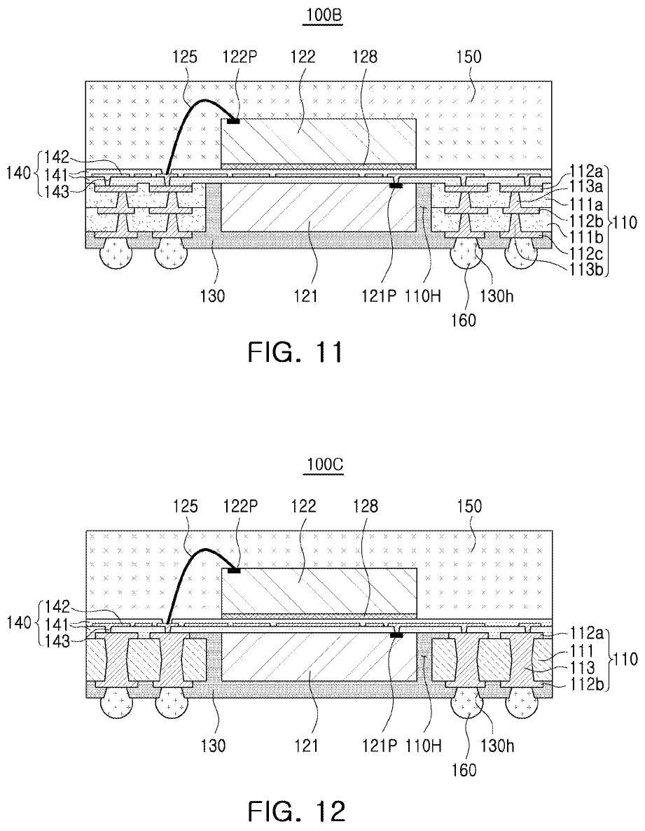

FIG. 11 is a schematic cross-sectional view illustrating another example of a fan-out semiconductor package.

Referring to FIG. 11, a fan-out semiconductor package 100B according to another example embodiment includes a frame 110 further including a first insulating layer 111a disposed in contact with a connection structure 140, a first wiring layer 112a embedded in the first insulating layer 111a while being in contact with the connection structure 140, a second wiring layer 112b disposed on a side opposing a side of the first insulating layer 111a in which the first wiring layer 112a is embedded, a first connection via layer 113a penetrating through the first insulating layer 111a and electrically connecting the first and second wiring layers 112a and 112b to each other, a second insulating layer 111b disposed on a side opposing a side of the first insulating layer 111a in which the first wiring layer 112a is embedded, a third wiring layer 112c disposed on a side opposing a side of the second insulating layer 111b in which the second wiring layer 112b is embedded, and a second connection via layer 113b penetrating through the second insulating layer 111b and electrically connecting the second and third wiring layers 112b and 112c to each other. The first to third wiring layers 112a, 112b, and 112c are electrically connected to a redistribution layer 142. For example, the frame 110 includes a greater number of insulating layers, wiring layers, and connection via layers, so that a design of the connection structure 140 may be further simplified to address a yield issue arising when the connection structure 140 is formed. The other descriptions are substantially the same as described with reference to FIGS. 9 and 10, and will be omitted herein.

FIG. 12 is a schematic cross-sectional view illustrating another example of a fan-out semiconductor package.

Referring to FIG. 12, as compared to the above-described fan-out semiconductor package 100A, a fan-out semiconductor package 100C according to another exemplary embodiment of the present disclosure includes a frame 110 including an insulating layer 111a, first and second wiring layers 112a and 112b respectively disposed on both surfaces of the insulating layer 111, and a connection via layer 113 penetrating through the insulating layer 111 and electrically connecting the first and second wiring layers 112a and 112b to each other. The first and second wiring layers 112a and 112b are electrically connected to a redistribution layer 142. As described above, the frame 110 may has a structure in which a pattern protrudes to both sides. In this case, the frame 110 may be formed using a copper clad laminate (CCL) or the like, which may result in simplified manufacturing and superior rigidity. The connection via layer 113 may have a cylindrical shape or an hourglass shape. The first semiconductor chip 121 may have a first active surface coplanar with surfaces of a first encapsulant 130 and the first wiring layer 112a, each being in contact with a connection structure 140. The other descriptions are substantially the same as described with reference to FIGS. 9 to 11, and will be omitted herein.

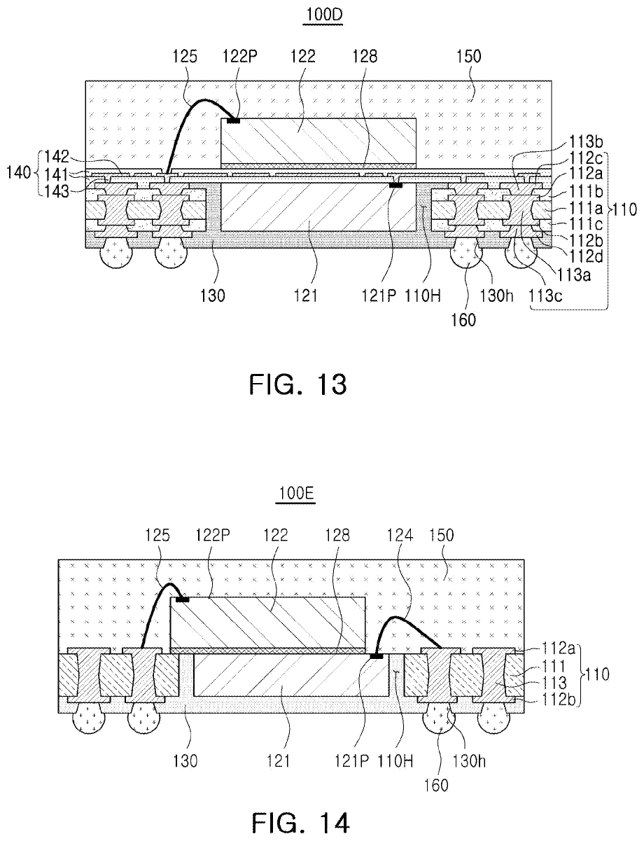

FIG. 13 is a schematic cross-sectional view illustrating another example of a fan-out semiconductor package.

Referring to FIG. 13, as compared to the above-described fan-out semiconductor package 100A, a fan-out semiconductor package 100D includes a frame 110 including a first insulating layer 111a, a first wiring layer 112a and a second wiring layer 112b respectively disposed on both surfaces of the first insulating layer 111a, a second insulating layer 111b, disposed on a top surface of the first insulating layer 111a on the basis of the drawing, covering the first wiring layer 112a, a third wiring layer 112c disposed on a top surface of the second insulating layer 111b on the basis of the drawing, a third insulating layer 111c, disposed on a bottom surface of the first insulating layer 111a on the basis of the drawing, covering the second wiring layer 112b, a fourth wiring layer 112d disposed on a bottom surface of the third insulating layer 111c on the basis of the drawing, and first third connection via layers 113a, 113b, and 113c respectively penetrating the first to third insulating layers 111a, 111b, and 111c, and electrically connecting first to fourth wiring layers 112a, 112b, 112c, and 112d. For example, the frame 110 may include a larger number of insulating layers, wiring layers, and connection via layers, so that a design of the connection structure 140 may be further simplified. In addition, the frame 110 may be formed using a CCL or the like, which may result in simplified manufacturing and superior rigidity. The first insulating layer 111a may have a thickness smaller than a thickness of each of the second and third insulating layers 111b and 111c. The first insulating layer 111a may basically have a relatively greater thickness to maintain rigidity, and the second and third insulating layers 111b and 111c may be introduced to form a greater number of wiring layers 112c and 112d. The first insulating layer 111a may include a copper clad laminate (CCL) or an unclad CCL, and each of the second and third insulating layers 111b and 111c may include a prepreg or an ABF, but materials thereof are not limited thereto. The other descriptions are substantially the same as described with reference to FIGS. 9 to 12, and will be omitted herein.

FIG. 14 is a schematic cross-sectional view illustrating another example of a fan-out semiconductor package.

Referring to FIG. 14, as compared to the above-described fan-out semiconductor package 100A, a fan-out semiconductor package 100E may include a frame 110 having a through-hole 110H and including a wiring layer 112, and a first semiconductor chip 121, disposed in the through-hole 110H of the frame 110. The first semiconductor chip 121 may have a first active surface, on which a first connection pad 121P is disposed, and a first inactive surface opposing the first active surface. The fan-out semiconductor package 100E may further include a first encapsulant 130 covering at least a portion of the first semiconductor chip 121. A second semiconductor chip 122 may be disposed on one surface of the first semiconductor chip 121, and have a second active surface, on which a second connection pad 122P is disposed, and a second inactive surface opposing the second active surface. Here, the second inactive surface may face the first active surface of the first semiconductor chip 121.

The first and second semiconductor chips 121 and 122 may be arranged to be dislocated with respect to a direction perpendicular to a stacking direction such that the first connection pad 121P can be exposed.

The first connection pad 121P may be electrically connected to the one or more wiring layers 112 by a first wire 124, and the second connection pad 122P may be electrically connected to the one or more wiring layers 112 by a second wire 125, such that the first and second connection pads 121P and 122P can be electrically connected to each other through the one or more wiring layers 112.

The fan-out semiconductor package 100E may further include a second encapsulant 150, disposed on one surface of the frame 110, covering at least a portion of the second semiconductor chip 122.

As described above, a fan-out semiconductor package, having less signal loss, which may be thinned even if the fan-out semiconductor package includes a plurality of semiconductor chips, may be provided.

In the present disclosure, the terms “lower side,” “lower portion”, “lower surface,” and the like, have been used to indicate a direction toward amounted surface of the electronic component package in relation to cross sections of the drawings, the terms “upper side,” “upper portion,” “upper surface,” and the like, have been used to indicate an opposite direction to the direction indicated by the terms “lower side,” “lower portion,” “lower surface,” and the like. However, these directions are defined for convenience of explanation only, and the claims are not particularly limited by the directions defined, as described above.

The meaning of a “connection” of a component to another component in the description includes an indirect connection through an adhesive layer as well as a direct connection between two components. In addition, “electrically connected” means including a physical connection and a physical disconnection. It can be understood that when an element is referred to as “first” and “second,” the element is not limited thereby. These terms may be used only for a purpose of distinguishing the element from the other elements, and may not limit the sequence or importance of the elements. In some cases, a first element may be referred to as a second element without departing from the scope of the claims set forth herein. Similarly, a second element may also be referred to as a first element.

The term “an example embodiment” used herein does not always refer to the same example embodiment, and is provided to emphasize a particular feature or characteristic different from that of another example embodiment. However, example embodiments provided herein are considered to be able to be implemented by being combined in whole or in part one with another. For example, one element described in a particular example embodiment, even if it is not described in another example embodiment, may be understood as a description related to another example embodiment, unless an opposite or contradictory description is provided therein.

Terms used herein are used only in order to describe an example embodiment rather than to limit the present disclosure. In this case, singular forms include plural forms unless necessarily interpreted otherwise, based on a particular context.

While example embodiments have been shown and described above, it will be apparent to those skilled in the art that modifications and variations could be made without departing from the scope of the present disclosure as defined by the appended claims.

What is claimed is:

1. A fan-out semiconductor package comprising:
a connection structure including one or more redistribution layers;
a first semiconductor chip, disposed on a first surface of the connection structure, having a first active surface, on which a first connection pad is disposed, and a first inactive surface opposing the first active surface, the first active surface facing the first surface of the connection structure;
a first encapsulant, disposed on the first surface of the connection structure, covering at least a portion of the first semiconductor chip; and
a second semiconductor chip, disposed on a second surface of the connection structure opposing the first surface, having a second active surface, on which a second connection pad is disposed, and a second inactive surface opposing the second active surface, the second inactive surface facing the second surface of the connection structure,
wherein the first connection pad is electrically connected to the one or more redistribution layers by a connection via of the connection structure,
the second connection pad is electrically connected to the one or more redistribution layers by a wire, and
the first and second connection pads are electrically connected to each other through the one or more redistribution layers.

2. The fan-out semiconductor package of claim 1, wherein the first active surface of the first semiconductor chip is in contact with the first surface of the connection structure, and
the second inactive surface of the second semiconductor chip is attached to the second surface of the connection structure via an adhesive.

3. The fan-out semiconductor package of claim 1, wherein the first active surface of the first semiconductor chip is coplanar with a surface of the first encapsulant in contact with the first surface of the connection structure.

4. The fan-out semiconductor package of claim 1, further comprising:
a frame, disposed on the first surface of the connection structure, having a through-hole and including one or more wiring layers,
wherein the first semiconductor chip is disposed in the through-hole, and
the first encapsulant covers at least a portion of the frame and is disposed in at least a portion of the through-hole.

5. The fan-out semiconductor package of claim 4, further comprising:
a plurality of openings penetrating through at least a portion of the first encapsulant covering a lower surface of the frame opposing an upper surface of the frame, on which the connection structure is disposed, the plurality of openings respectively exposing at least a portion of a wiring layer disposed on the lower surface of the frame; and
a plurality of electrical connection metals, respectively disposed in the plurality of openings, each being electrically connected to the wiring layer.

6. The fan-out semiconductor package of claim 5, wherein the plurality of electrical connection metals are disposed only in a fan-out region, the fan-out region including a region except a region in which the first semiconductor chip is disposed from a viewpoint perpendicular to a stacking direction.

7. The fan-out semiconductor package of claim 4, wherein the frame includes:
a first insulating layer;
a first wiring layer disposed in contact with the connection structure and embedded in the first insulating layer;
a second wiring layer disposed on a lower side of the first insulating layer opposing an upper side of the first insulating layer in which the first wiring layer is embedded; and
a first connection via layer penetrating through the first insulating layer and electrically connecting the first and second wiring layers to each other, and
the first and second wiring layers are electrically connected to the one or more redistribution layers.

8. The fan-out semiconductor package of claim 7, wherein the first active surface of the first semiconductor chip is coplanar with a surface of the first insulating layer in contact with the first surface of the connection structure.

9. The fan-out semiconductor package of claim 7, wherein the frame further includes:
a second insulating layer disposed on the lower side of the first insulating layer and covering the second wiring layer;
a third wiring layer disposed on a lower side of the second insulating layer opposing an upper side of the second insulating layer in which the second wiring layer is embedded; and
a second connection via electrically connecting the second and third wiring layers to each other, and
the third wiring layer is electrically connected to the one or more redistribution layers.

10. The fan-out semiconductor package of claim 7, wherein a surface of the first insulating layer, disposed in contact with the first surface of the connection structure, has a step with respect to a surface of the first wiring layer disposed in contact with the first surface of the connection structure.

11. The fan-out semiconductor package of claim 4, wherein the frame includes:
a first insulating layer;
a first wiring layer and a second wiring layer respectively disposed on both surfaces of the first insulating layer; and
a first connection via layer penetrating through the first insulating layer and electrically connecting the first and second wiring layers to each other, and
the first and second wiring layers are electrically connected to the one or more redistribution layers.

12. The fan-out semiconductor package of claim 11, wherein the frame further includes:
a second insulating layer disposed on one surface of the first insulating layer to cover the first wiring layer;
a third wiring layer disposed on an upper side of the second insulating layer opposing a lower side of the second insulating layer in which the first wiring layer is embedded;
a second connection via layer penetrating through the second insulating layer and electrically connecting the first and third wiring layers to each other;
a third insulating layer disposed on another surface of the first insulating layer to cover the second wiring layer;
a fourth wiring layer disposed on a lower side of the third insulating layer opposing an upper side of the third insulating layer in which the second wiring layer is embedded; and
a third connection via layer penetrating through the third insulating layer and electrically connecting the second and fourth wiring layers to each other, and
the third and fourth wiring layers are electrically connected to the one or more redistribution layers.

13. The fan-out semiconductor package of claim 12, wherein the first insulating layer has a thickness greater than a thickness of each of the second and third insulating layers.

14. The fan-out semiconductor package of claim 1, further comprising:
a second encapsulant, disposed on the second surface of the connection structure, covering at least a portion of each of the second semiconductor chip and the wire.

15. The fan-out semiconductor package of claim 1, wherein the first and second semiconductor chips are homogeneous integrated circuit dies.

16. The fan-out semiconductor package of claim 15, wherein the first and second semiconductor chips are homogeneous memories.

17. The fan-out semiconductor package of claim 1, further comprising a second encapsulant, disposed on the second surface of the connection structure, covering at least a portion of the second semiconductor chip.

18. The fan-out semiconductor package of claim 17, wherein the second encapsulant covers a second inactive surface and a side surface of the second semiconductor chip, and
the second encapsulant covers at least a portion of the wire.

19. A fan-out semiconductor package comprising:
a frame having a through-hole and including one or more wiring layers;
a first semiconductor chip, disposed in the through-hole of the frame, having a first active surface, on which a first connection pad is disposed, and a first inactive surface opposing the first active surface;
a first encapsulant covering at least a portion of the first semiconductor chip; and
a second semiconductor chip, disposed on one surface of the first semiconductor chip, having a second active surface, on which a second connection pad is disposed, and a second inactive surface opposing the second active surface, the second inactive surface facing the first active surface of the first semiconductor chip,
wherein the first and second semiconductor chips are arranged to be dislocated with respect to a direction perpendicular to a stacking direction such that the first connection pad is exposed,
the first connection pad is electrically connected to the one or more wiring layers by a first wire,
the second connection pad is electrically connected to the one or more wiring layers by a second wire, and
the first and second connection pads are electrically connected to each other through the one or more wiring layers.

20. The fan-out semiconductor package of claim 19, further comprising a second encapsulant, disposed on one surface of the frame, covering at least a portion of the second semiconductor chip.
